(19) United States
(12) Patent Application Publication
(10) Pub. No.: US 2018/0115338 A1
(43) Pub. Date: Apr. 26, 2018

(54) Device to Protect Portable Electronic Systems

(71) Applicants: James Hermanowski, Waterbury, VT (US); Sherri Hermanowski, Waterbury, VT (US); Yvette Randolph, Waterbury, VT (US)

(72) Inventors: James Hermanowski, Waterbury, VT (US); Sherri Hermanowski, Waterbury, VT (US); Yvette Randolph, Waterbury, VT (US)

(21) Appl. No.: 15/333,392

(22) Filed: Oct. 25, 2016

(51) Int. Cl. H04B 1/3888; H05K 7/20

(52) U.S. Cl. CPC H04B 1/3888; H05K 7/20; H05K 7/2039

(57) ABSTRACT

For use with portable electronic devices, a protective system consisting of a multi-functional outer shell having various types of thermal and mechanical properties with inner pockets for holding additional thermally protective elements which are combined in a single unit and useful in providing thermal protection to portable electronic devices which are positioned within the outer shell.

### BACKGROUND OF THE INVENTION

Portable electronic devices (PEDs), such as cellular phones, personal digital assistants (PDAs), tablet computers, laptop computers, global positioning systems (GPS) and music players, have grown in popularity in recent years. Consumers find benefit from easy access to information and entertainment they provide at their disposal twenty-four hours per day, seven days per week. Consumers carry such devices everywhere. The devices are used at locations ranging from one extreme to another; for example, a hot sunny beach to a cold mountaintop ski slope; from a dry desert to a water park. Portable electronic devices can be especially important during emergency situations allowing the user to navigate out of an area or call for assistance, while authorities can use their signals or GPS coordinates to pinpoint the user's location to dispatch assistance. Unfortunately, widely used portable electronic devices are not designed to survive under severe conditions when they would be needed most.

The complexity of portable electronic devices and their target for mass production for everyday consumer use makes them vulnerable to breakage and failure especially when dropped on hard surfaces, exposed to water or exposed to extreme heat and cold. Those experienced in the art recognize the basic construction of portable electronic device consists of a protective case, a user interface such as a liquid crystal display (LCD) on the outside of a case, an input mechanism such as a keyboard, dial, buttons or touch screen on the outside of the case, a computing device within the case and a power supply such as a battery inside the case.

Many types of portable electronic devices are available in a ruggedized design to withstand certain hazards, however, these devices are designed to address specific needs, are heavier, bulkier and do not enjoy the low cost advantage from mass production as their consumer oriented versions. In an attempt to overcome this problem, those skilled in the art have attempted to extend the survivability of portable electronic devices by designing protective cases which can protect the portable electronic devices while in use or during transport, etc. There are numerous designs for various protective cases and sleeves that are known in the prior art, twelve examples follow.

1. U.S. Design Pat. No. D610,807 issued to Steven Chi Vun Bau on Mar. 2, 2010 for Protective Case For Portable Handheld Electronic Device”;

### 2. United States Published Patent Application No. 2010/0203931 to Bryan Lee Hynecek et al. on Aug. 12, 2010 for “One Piece Co-Formed Exterior Hard Shell Case With An Elastomeric Liner For Mobile Electric Devices”;

3. Chinese Patent No. CN201499752 issued to Mudan Yao on Jun. 9, 2010 for “Mobile Phone Protection Sleeve”;
4. Chinese Patent No. CN202261424 issued to Tian Hui Zhu on May 30, 2012 for “An Anti-Falling Anti-Slip Hand Casing”
5. U.S. Pat. No. 6,297,236 issued to Seok,
6. U.S. Pat. No. 5,632,373 issued to Kumar et al.
7. U.S. Pat. No. 5,214,574 issued to Chang.
8. U.S. Pat. No. 7,230,823 issued to Curtis R. Richardson et al. on Jun. 12, 2007 for “Protective Membrane For Touch Screen Device”;
9. U.S. Design Pat. No. D606,305 issued to Edmund S. Lee et al. on Dec. 22, 2009 for “Mobile Media Device Enclosure”;
10. U.S. Pat. No. 7,933,122 issued to Curtis R. Richardson et al. on Apr. 26, 2011 for Protective Enclosure For A Computer”;

### 11. United States Published Patent Application No. 2010/0104814 to Curtis Richardson et al. on Apr. 29, 2010 for “Protective Cushion Cover For An Electronic Device”;

### 12. United States Published Patent Application No. 2010/0096284 to Steven Chi Vun Bau on Apr. 22, 2010 for “Protective Case Having A Hybrid Structure For Portable Handheld Electronic Devices”.

The above designs provide mechanical protections of the electronic device from dropping, shock and or water intrusion using a variety of solutions including hard mechanical covers, soft mechanical covers, combination hard and soft covers, water resistant membranes and anti-slip covers. An example of such a device is shown in FIG. 1.
However, these designs do not address temperature extremes. Major components of the PED cannot tolerate temperature extremes. The computer chips inside the PED are sensitive to heat and can fail permanently and prematurely when overheated. Portable batteries degrade rapidly at high temperatures, fail prematurely and may even explode. Liquid crystal displays become distorted or discolored and can delaminate at high temperatures. Mechanical input devices can become distorted and malfunction while touch screens can become unresponsive. At the other temperature extreme, freezing temperatures, portable batteries stop functioning even when fully charged. LCDs become unresponsive and can turn blue while at freezing temperatures. Freezing temperatures can also mechanically distort the positioning of input mechanisms and cause them to malfunction. Portable electronic devices can be so temperature sensitive that their operating limits can be easily exceeded during conditions encountered by their owners, for example during a summer day or while outside during winter. According to Apple's technical specifications, the operating ambient temperature specification for the Apple iPhone 6S is 32 degrees F. to 95 degrees F. The non-operating ambient temperature specification for the Apple iPhone 6S is −4 degrees F. to 113 degrees F. Both conditions require noncondensing humidity conditions from 5% to 95%. The cost of repairing or replacing such a device from thermal damage can exceed several hundred dollars.

Alternate designs have provided cold climate protection for the battery in a portable electronic device. U.S. Pat. No. 6,575,156, Jun. 10, 2003 granted to MacFarlane et al. for a battery warmer is one such example. However, the design lacks protection for the other temperature sensitive elements of the PED such as the display and the input mechanisms. The inclusion of a heating element as described in 6575156 creates conditions where the unprotected portions of the device remain exposed to cold or freezing temperatures and are subsequently subjected to condensation. Depending on the temperature and humidity at and near the PED, the amount of condensation deposited on the electronic device can be copious and catastrophic. Furthermore, 6575156 does nothing to protect the battery or PED from exposure to extreme heat conditions.

Another battery warmer found in U.S. Pat. No. 8,574,738, Nov. 5, 2013 granted to Fattig uses an integrated heater and the battery itself to provide energy to keep a lithium ion battery warm. The main drawback of this approach is that the energy for heating is withdrawn from the same battery used for the device, increasing the load on the battery and reducing the energy available for the device. Another battery heating system, U.S. Pat. No. 7,947,925, May 24, 2011 by Suzuki et al. describes a system whereby a secondary battery provides heat for the primary battery. In this approach, the battery providing heat is brought into close proximity to the battery to be heated. The increased size and weight of this approach is not suitable to the requirements of portable electronic devices. Additionally, neither approach protects the battery from extreme heat conditions.

As apparent from the above examples a need exists to protect a portable electronic device from both high and low temperature extremes. An improved system must protect the entire portable electronic device, not just the battery, from heat and cold.

### SUMMARY OF THE INVENTION

Some example aspects of the present invention relate to protective device structures that have excellent thermal resistive and thermal insulative properties while reducing device bulk, weight and/or packability. These and other advantageous properties may be realized in accordance with examples of this invention, by providing a device structure including targeted zones of increased thermal resistive and increased thermal insulative properties. Additionally, the present invention addresses the problems previously outlined by providing an outer sleeve consisting of an outmost multi-functional structure with multiple internal pockets containing active and/or passive thermal management elements used to encase and protect the PED.

### DETAILED DESCRIPTION OF THE INVENTION

The object of the present invention is to create a unique device to protect a cell phone or other portable electronic device which contains a unique combination of an outer sleeve consisting of a multi-functional structure forming a top, a bottom and three connecting sidewalls cooperatively defining a space for the portable electronic device and two thermal management elements configured on either major side of the PED. The outer sleeve contains further provisions for two sleeves attached to the top and bottom of the outer sleeve respectively while retaining a center portion of the space to receive the portable electronic device. The sleeves are configured for the easy insertion and removal of thermal management elements. The structure of the multi-functional outer sleeve consists of layers that are selected to provide mechanical protection of the PED, a thermal barrier and/or a heat reflector.

### BRIEF DESCRIPTION OF THE DRAWINGS

FIG. 1 shows an example of prior art, U.S. Pat. No. 8,439,191, providing mechanical protection without additional thermal protection and incorporated herein by reference.

FIG. 2 shows an example cross section of a multi-functional outer shell consisting of three sections.

FIG. 3 shows an example cross section of a device to protect portable electronic systems. The cross section shows the interface between the invention and a portable electronic system 300 in place at the center.

FIG. 4 shows an example cross section of a device to protect portable electronic systems. The cross section leaves a central cavity available to accept a portable electronic device.

FIG. 5 shows one an embodiment of the present invention.

FIG. 6 shows examples of the present invention in use in the case where it is carried or stored within clothing of an individual.

FIG. 7 shows examples of the present invention in the case where it is exposed to the environment allowing the outer shell to reduce the penetration and impact of a heat generating source such as the sun on the PED.

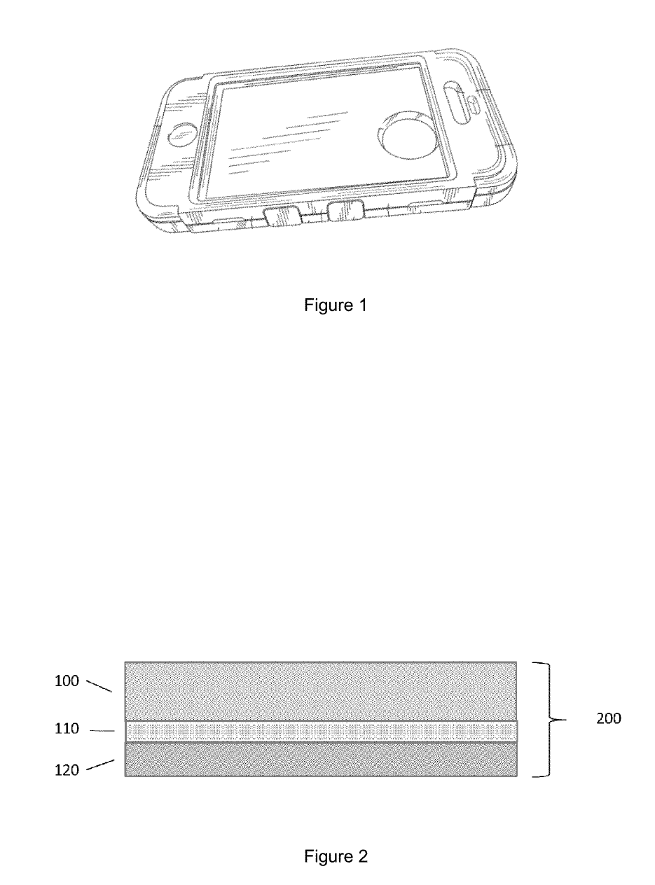

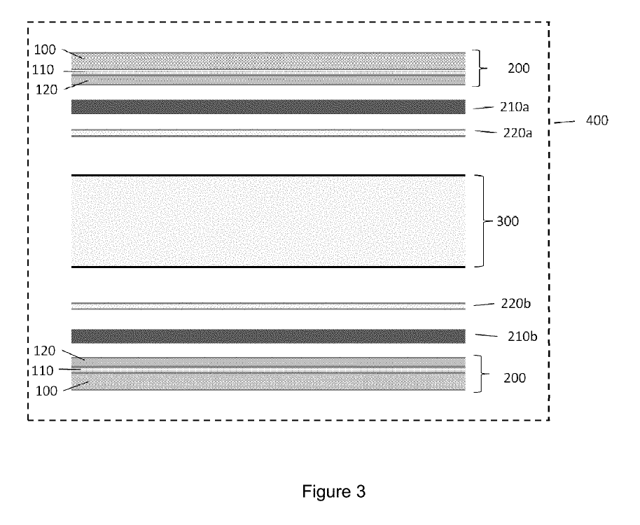

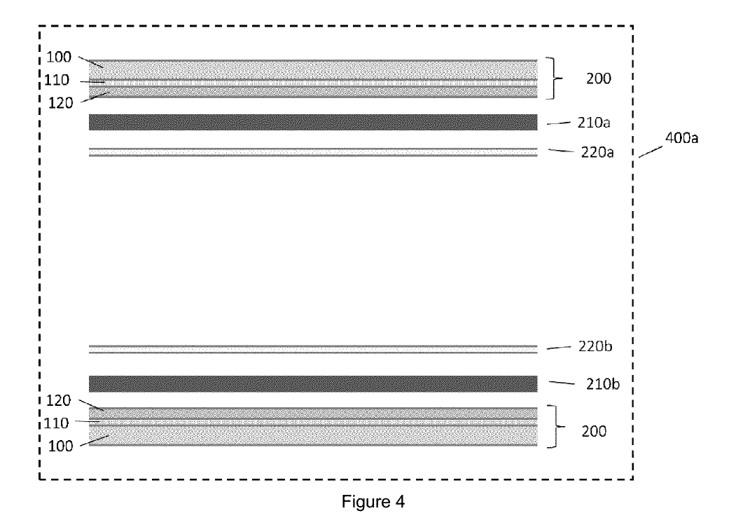

### DESCRIPTION OF THE PREFERRED EMBODIMENTS

The present invention now will be described more fully hereinafter with reference to the accompanying drawings, in which some examples of the embodiments of the invention are reviewed. The use of these examples by no means limits the scope of the invention as those skilled in the art will recognize the value obtained from various combinations of elements of the present invention.

In an embodiment of the present invention, the outer shell 200 is shown in cross section detail in FIG. 2. The shell consists of multiple layers 100, 110 and 120 where the upper surface of 100 represents the outside of the outer shell and the lower surface of 120 represents the area defined by the inner portion of the shell. In a preferred embodiment, layer 100 consists of a mechanically durable material such as leather or vinyl. Layer 110 consists of a heat reflective layer such as aluminized mylar, metalized fabric or lightly colored fabric. Layer 120 consists of a thermal insulating material, for example, wool, rayon, cotton or polyester.

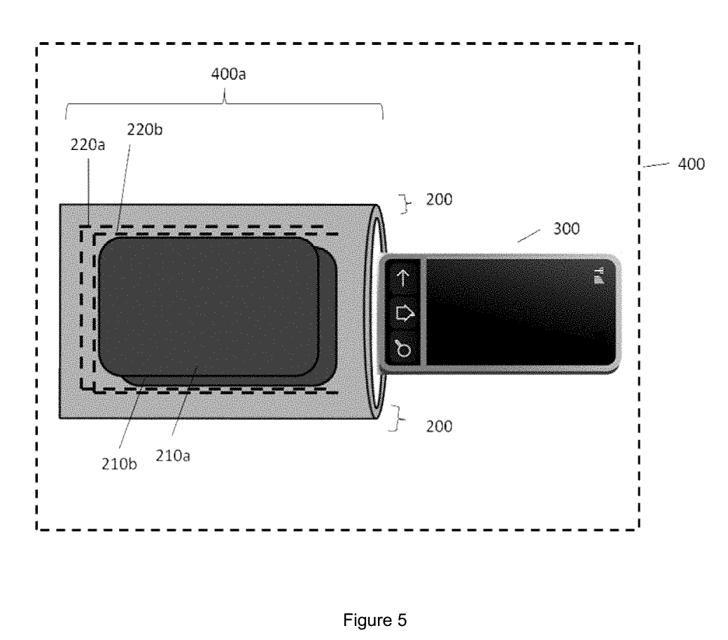

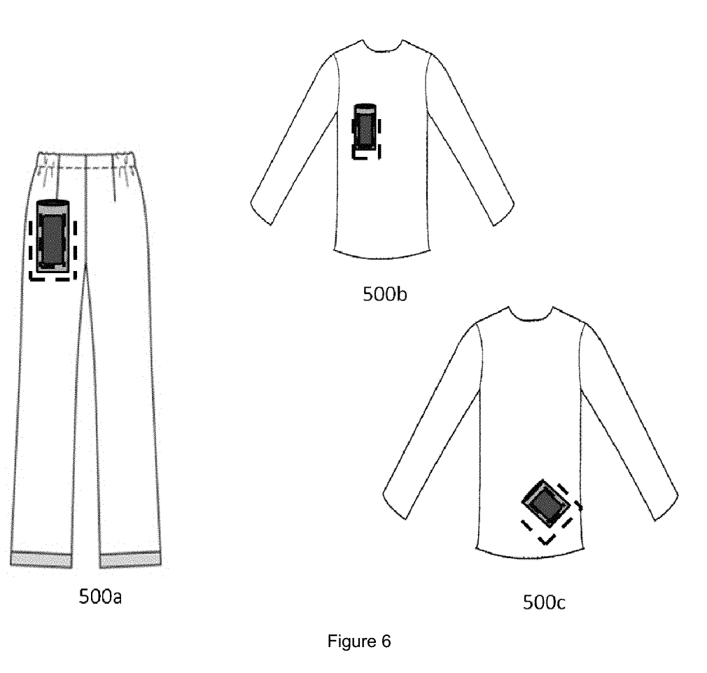

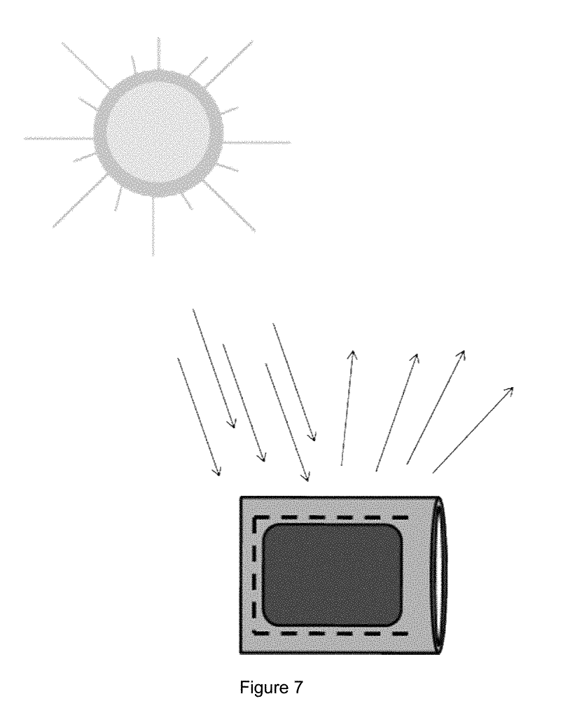

The outer shell is formed into the shape of a container or pouch formed from three sides, a top and a bottom 400a, with an opening to accept a portable electronic device, 300 shown in FIG. 5. The insertion of PED 300 into the protective device 400a creates an assembly 400, also shown in FIG. 5. 210a and 210b are thermal management devices that can be easily removed and replaced as needed to offer protection against heat or cold. 220a and 220b form envelopes designed to hold thermal management devices 210a and 210b. 220a and 220b consist of thermally permeable materials, for example, a thin fabric.

For protection against overheating of the PED the preferred embodiments of 210a and 210b consist of a gel-based cooling pad that may be refrigerated prior to use to provide active cooling. Those skilled in the art will recognize that alternate suitable elements exist to protect the PED from heat, for example, an expanded polystyrene sheet. For protection of the PED against cold conditions the preferred embodiments of 210a and 210b consist of self contained heating elements. The heating elements are capable of generating heat as a result of a chemical reaction that is initiated by a method selected from the group consisting of pressing a button or physical manipulation of the heating element. Those skilled in the art will recognize that alternate suitable heating elements exist, for example, a gel-based heating pad heated prior to use, or a flameless catalytic heater.

What we claim is:

1. A device for regulating the temperature of portable electronic systems comprising:
a pouch consisting of a multi-functional structure forming at least a top, a bottom and three connecting sidewalls cooperatively defining a center space to receive the portable electronic system. The pouch contains further provisions for outer sleeves attached to the top and bottom of and surrounding the center space respectively capable of receiving thermal regulating elements.

2. The invention of claim 1, wherein said multi-functional structure consists of at least two layers capable of exhibiting desired properties selected from among mechanically durable materials, radiant reflective materials or heat insulating materials.

3. The invention of claim 1, whereby said outer sleeves contain heat removal devices consisting of a heat absorbing substance taken from the group consisting of precooled ice packs, precooled gel packs, or single use instant ice packs created from an endothermic chemical reaction.

4. The invention of claim 1, whereby said outer sleeves contain heat generating devices taken from the group consisting of preheated gel packs; heat packs created by an exothermic reaction, for example using sodium acetate; single use heating elements created from an exothermic chemical reaction for example by oxidation of iron or charcoal; or heating elements created by exothermic catalytic reduction of organic molecules.

5. The invention of claim 1, whereby said outer sleeves contain passive thermal barrier material taken from the group consisting of polystyrene; wool; urethane foam; cotton; or synthetic fibers.

6. The invention of claim 2, wherein said multi-functional structure consists of at least one layer capable of exhibiting at least two desired properties selected from among mechanically durable materials, radiant reflective materials or heat insulating materials.

7. The invention of claim 1, wherein said multi-functional structure consists of a layer of mechanically durable material, a second layer of radiant reflective material and a third layer of heat insulating material.
